(19) United States
(12) Patent Application Publication
(10) Pub. No.: US 2023/0411545 A1
(43) Pub. Date: Dec. 21, 2023

(54) TABBING APPARATUS AND TABBING METHOD USING THE SAME

(71) Applicant: HANWHA CORPORATION, Seoul (KR)

(72) Inventors: Sung Gyu JEON, Seoul (KR); Dong Jin CHUNG, Seoul (KR); Min Kyo JUNG, Seoul (KR)

(73) Assignee: HANWHA CORPORATION, Seoul (KR)

(21) Appl. No.: 18/210,401

(22) Filed: Jun. 15, 2023

(30) Foreign Application Priority Data
Jun. 16, 2022 (KR) 10-2022-0073452
Jun. 17, 2022 (KR) 10-2022-0074170

(51) Int. Cl. H01L 31/05; H01L 31/18

(52) U.S. Cl. CPC H01L 31/05; H01L 31/18

(57) ABSTRACT

A tabbing apparatus for forming a solar cell module by connecting a solar cell with a wire includes: a solar cell transportation apparatus configured to transport the solar cell; a wire transportation apparatus configured to transport the wire; a wire jig transportation apparatus configured to transport a wire jig that is configured to support the wire; an alignment apparatus configured to mount thereon the solar cell transported by the solar cell transportation apparatus, and correct a position of the solar cell; and a delivering apparatus configured to support the solar cell mounted on the alignment apparatus and having the corrected position and the wire jig transported by the wire jig transportation apparatus, and mount the solar cell and the wire jig on the wire on the wire transportation apparatus.

### CROSS-REFERENCE TO RELATED APPLICATIONS

This application is based on and claims priority under 35 U.S.C. § 119 to Korean Patent Application Nos. 10-2022-0073452 and 10-2022-0074170, respectively filed on Jun. 16, 2022 and Jun. 17, 2022, in the Korean Intellectual Property Office, the disclosures of which are incorporated by reference herein in their entireties.

### BACKGROUND

### 1. Field

The disclosure relates to a tabbing apparatus and a tabbing method using the same.

### 2. Description of the Related Art

A solar cell, that is, a solar battery, is formed by arranging a p-n junction diode on a substrate. When sunlight is irradiated onto a solar cell, an exciton, which is a pair of an electron and a hole, is generated, and as the exciton is separated, the electron moves to an p-layer and the hole moves to a p-layer, so that a photoelectro-motive force is generated in a p-n junction. Tabbing refers to a process of forming a solar cell module by electrically connecting a plurality of solar cells by arranging a wire on the plurality of solar cells.

Generally, a tabbing apparatus includes a transportation apparatus for transporting a wire, and bonds a solar cell with the wire in a state in which the solar cell is arranged on the wire. Before the tabbing apparatus bonds the solar cell with the wire, the tabbing apparatus supports a wire jig for fixing the wire and the solar cell, and then, arranges the wire jig and the solar cell on the wire. Here, when relative positions among the solar cell, the wire jig, and the wire are not corrected, the solar cell and the wire may not be properly connected to each other, and for example, the wire may be floated, etc., to degrade the quality of the solar cell module.

The background art described above corresponds to technical information contained by the inventor to derive the disclosure or acquired in the process of deriving the disclosure and may not necessarily correspond to the well-known art publicly known before the application of the disclosure.

### SUMMARY

Provided are a tabbing apparatus and a tabbing method using the same, by which positions of a solar cell, a wire jig, and a wire may be aligned before the solar cell and the wire are connected to each other, and the solar cell and the wire jig may be simultaneously transported, thereby reducing time and costs for manufacturing a solar module.

However, this aspect of the disclosure is only an example, and the disclosure is not limited thereto.

Additional aspects will be set forth in part in the description which follows and, in part, will be apparent from the description, or may be learned by practice of the presented embodiments of the disclosure.

According to an aspect of the disclosure, there is provided a tabbing apparatus for forming a solar cell module by connecting a solar cell with a wire, which may include: a solar cell transportation apparatus configured to transport the solar cell; a wire transportation apparatus configured to transport the wire; a wire jig transportation apparatus configured to transport a wire jig that is configured to support the wire; an alignment apparatus configured to mount thereon the solar cell transported by the solar cell transportation apparatus, and correct a position of the solar cell; and a delivering apparatus configured to support the solar cell mounted on the alignment apparatus and having the corrected position and the wire jig transported by the wire jig transportation apparatus, and mount the solar cell and the wire jig on the wire on the wire transportation apparatus.

The alignment apparatus may include a plurality of displacement devices including a first displacement device movable in a direction of an X-axis, a second displacement device movable in a direction of a Y-axis, and a third displacement device rotatable with respect to a Z-axis.

The tabbing apparatus may further include: a controller; and a position identification sensor configured to identify the position of the solar cell mounted on the alignment apparatus, wherein the controller is configured to correct the position of the solar cell, by controlling the alignment apparatus based on the position of the solar cell identified by the position identification sensor and a pre-stored reference value, and wherein the controller is configured to control the alignment apparatus based on one or more of position information about the wire transportation apparatus and position information about the wire jig transportation apparatus as the reference value.

After the delivering apparatus simultaneously supports the solar cell, the position of which is corrected by the alignment apparatus, and the wire jig, the delivering apparatus may move to the wire transportation apparatus and simultaneously mount the solar cell and the wire jig on the wire.

The wire jig transportation apparatus may include a stopper at an end thereof adjacent to the alignment apparatus, the stopper contacting the wire jig, and the delivering apparatus may simultaneously support the solar cell mounted on the alignment apparatus and the wire jig contacting the stopper.

The delivering apparatus may further include a cell-jig transportation apparatus, and the cell jig transportation apparatus may include: a main body; a first movement structure connected to the main body to be movable in a first direction; a second movement structure connected to the main body to be movable in a second direction which is different from the first direction; and a first support structure and a second support structure each integrally moving with the second movement structure and respectively supporting the wire jig and the solar cell at a same time, wherein the first support structure comprises a first contact surface facing the wire jig, wherein the second support structure comprises a second contact surface facing the solar cell, and wherein the first contact surface and the second contact surface have different heights from each other.

The first contact surface may be arranged to be higher than the second contact surface, and a bottom surface of the wire jig and a bottom surface of the solar cell may be arranged on a same plane.

After the cell jig transportation apparatus simultaneously supports the solar cell mounted on the alignment apparatus and the wire jig transported by the wire jig transportation apparatus, the cell jig transportation apparatus may move along with the delivering apparatus and mount the solar cell and the wire jig on the wire mounted on the wire transportation apparatus.

The cell jig transportation apparatus may be provided in plural to be integrally movable through the delivering apparatus, and, after each of the plurality of cell-jig transportation apparatuses simultaneously supports the solar cell and the wire jig, each of the plurality of cell-jig transportation apparatuses may simultaneously mount the solar cell and the wire jig on the wire.

The plurality of cell-jig transportation apparatuses may include two cell-jig transportation apparatuses, and the main body of any one of the cell-jig transportation apparatuses may be arranged on the second support structure of the other cell jig transportation apparatus.

According to another aspect of the disclosure, there is provided a tabbing method of forming a solar cell module by connecting a solar cell with a wire. The method may include: transporting the solar cell, the wire, and a wire jig supporting the wire, respectively via a solar cell transportation apparatus, a wire transportation apparatus, and a wire jig transportation apparatus; correcting a position of the solar cell, using an alignment apparatus, while the alignment apparatus is supporting the solar cell transported by the solar cell transportation apparatus; and after supporting the solar cell and the wire jig using a delivering apparatus, moving to the wire transportation apparatus and mounting the solar cell and the wire jig on the wire using the delivering apparatus.

A position identification sensor may identify the position of the solar cell mounted on the alignment apparatus, a controller may correct the position of the solar cell in at least three different directions, by controlling the alignment apparatus based on the position of the solar cell, and the delivering apparatus may support the solar cell having the corrected position and the wire jig.

After the delivering apparatus simultaneously supports the solar cell and the wire jig, the delivering apparatus may move to the wire transportation apparatus and may simultaneously mount the solar cell and the wire jig on the wire.

The controller may correct the position of the solar cell based on the position of the solar cell and a pre-stored reference value, and the reference value may be one or more of position information of the wire transportation apparatus and position information about the wire jig transportation apparatus.

The wire jig transportation apparatus may include a stopper at an end thereof adjacent to the alignment apparatus, the stopper contacting the wire jig, may sequentially transport the wire jig in plural toward the stopper, and may transport a next wire jig after a predetermined time period so that the wire jig maintains a predetermined gap with a wire jig getting near after contacting the stopper.

The delivering apparatus may further include a cell-jig transportation apparatus, and the cell jig transportation apparatus may include: a main body; a first movement structure connected to the main body portion to be capable of relative movement in a first direction; a second movement structure connected to the main body to be capable of relative movement in a second direction which is different from the first direction, and a first support structure and a second support structure each integrally moving along with the second movement structure and respectively simultaneously supporting the wire jig and the solar cell, wherein the first support structure may include a first contact surface facing the wire jig, the second support structure may include a second contact surface facing the solar cell, and the first contact surface and the second contact surface may have different heights from each other.

The first contact surface may be arranged to be higher than the second contact surface, and a bottom surface of the wire jig and a bottom surface of the solar cell may be arranged on a same plane.

After the cell jig transportation apparatus simultaneously supports the solar cell mounted on the alignment apparatus and the wire jig transported by the wire jig transportation apparatus, the cell jig transportation apparatus may move along with the delivering apparatus and mount the solar cell and the wire jig on the wire mounted on the wire transportation apparatus.

The cell jig transportation apparatus may be provided in plural to be integrally movable through the delivering apparatus, and, after each of the plurality of cell-jig transportation apparatuses simultaneously supports the solar cell and the wire jig, each of the plurality of cell-jig transportation apparatuses may simultaneously mount the solar cell and the wire jig on the wire.

The plurality of cell-jig transportation apparatuses may include two cell-jig transportation apparatuses, and the main body of any one of the cell-jig transportation apparatuses may be arranged on the second support structure of the other cell jig transportation apparatus.

The above and other aspects, features, and advantages will be more apparent from the following description taken in conjunction with the detailed description, claims, and accompanying drawings.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 schematically illustrates a tabbing apparatus according to an embodiment;

FIG. 2 illustrates an alignment apparatus according to an embodiment;

FIG. 3 illustrates an operation of an alignment apparatus according to an embodiment;

FIG. 4 illustrates an alignment apparatus and a wire jig transportation apparatus according to an embodiment;

FIG. 5 is a perspective view of a cell jig transportation apparatus according to an embodiment;

FIG. 6 is a side view of a cell jig transportation apparatus according to an embodiment;

FIG. 7 is an enlarged view of a cell-jig transportation apparatus according to an embodiment;

FIG. 8 illustrates an enlarged view of a first support structure according to an embodiment;

FIG. 9 illustrates a bottom surface of a second support structure according to an embodiment;

FIGS. 10 and 11 illustrate an operation of a cell jig transportation apparatus according to an embodiment; and

FIG. 12 illustrates an operation of a cell-jig transportation apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments, which are example embodiments, may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

While the disclosure is capable of various modifications and alternative forms, embodiments thereof are shown by way of example in the drawings and will herein be described in detail. However, it shall be understood that the disclosure is not limited to the one or more embodiments, and all modifications, equivalents, and substitutes encompassed by the concept and the technical range of the disclosure are included in the disclosure. When describing the disclosure, the same components are indicated by using the same reference numerals, although the components are illustrated according to a different embodiment.

Hereinafter, embodiments of the disclosure will be described in detail by referring to the accompanying drawings. In descriptions with reference to the drawings, the same reference numerals are given to elements that are the same or substantially the same and descriptions will not be repeated.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

In the embodiments hereinafter, the x-axis, the y-axis and the z-axis are not limited to three axes of the rectangular coordinate system, and may be interpreted in a broader sense. The x-axis, the y-axis, and the z-axis may be perpendicular to one another, or may represent different directions that are not perpendicular to one another.

When a certain embodiment may be implemented differently, a specific process order may be performed differently from the described order. Two consecutively described processes may be performed substantially at the same time or performed in an order opposite to the described order.

Terms used in the present application are used only for describing particular embodiments of the disclosure and are not intended to limit the disclosure. With respect to the present application, it will be further understood that the terms “comprises” or “comprising” used herein specify the presence of stated features, integers, steps, operations, members, components, and/or groups thereof, but do not preclude the presence or addition of one or more other features, integers, steps, operations, members, components, and/or groups thereof.

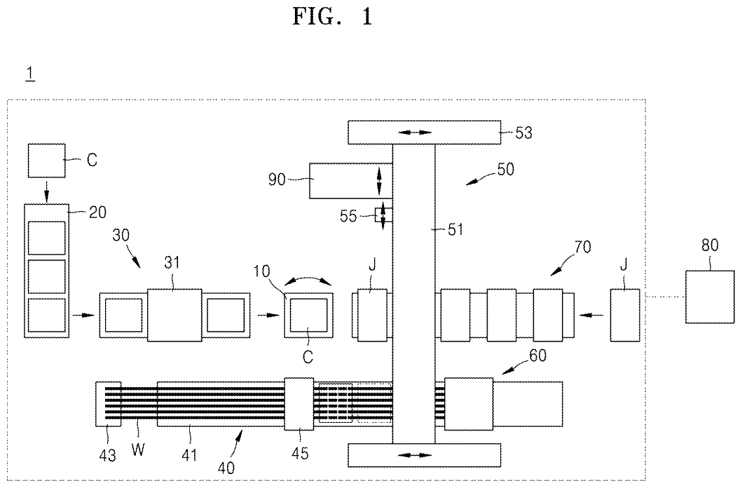

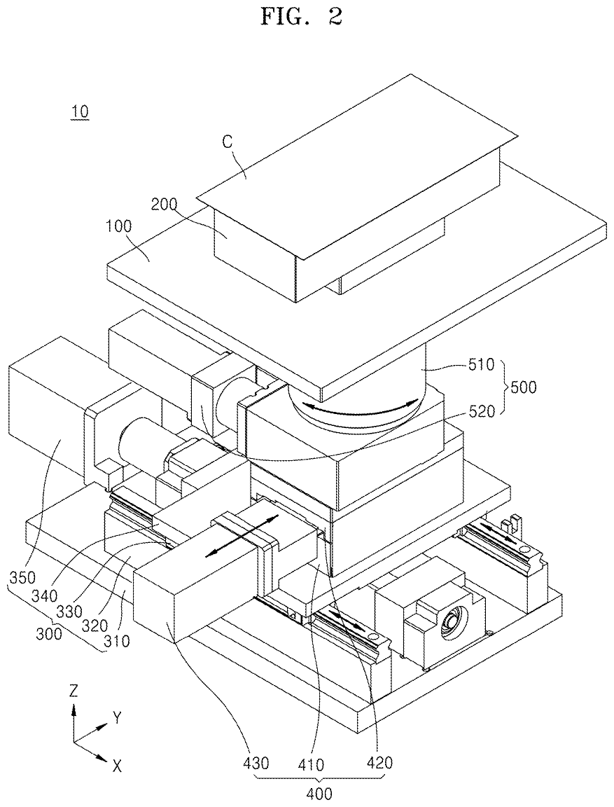

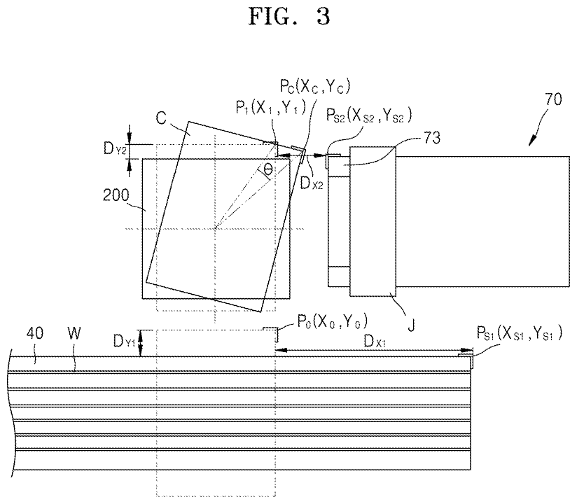

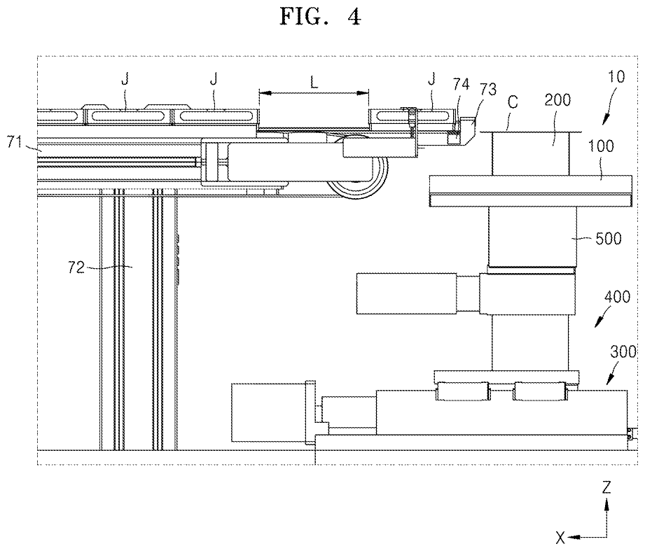

FIG. 1 schematically illustrates a tabbing apparatus 1 according to an embodiment, FIG. 2 illustrates an alignment apparatus 10 according to an embodiment, FIG. 3 illustrates an operation of the alignment apparatus 10 according to an embodiment, and FIG. 4 illustrates the alignment apparatus 10 and a wire jig transportation apparatus 70 according to an embodiment.

The tabbing apparatus 1 is an apparatus for forming a solar cell module by connecting a solar cell C with a wire W. The solar cell C includes a semiconductor junction area having a p-n junction surface, and when energy higher than or equal to a predetermined capacity is irradiated or applied to the solar cell C, the solar cell C may generate an electro-motive force which coverts light energy to electrical energy. A semiconductor material included in the solar cell C is not particularly limited, and may include silicon (monocrystalline, polycrystalline, and amorphous), gallium arsenic, cadmium telluride, cadmium sulfide, indium phosphide, copper indium gallium selenide (CIGS), organic dyes, or a compound thereof.

The wire W is a conductor for electrically connecting a plurality of solar cells C with each other, and connects a front surface of a solar cell C with a rear surface of an adjacent solar cell C. The wire W may be electrically connected onto the solar cell C through a soldering process. Alternatively, the wire W may be electrically connected onto the solar cell C through an electrically conductive adhesive (ECA).

A plurality of solar cells C and a plurality of wires W may be electrically connected to each other to form a solar cell module. The solar cell module may be formed by including the wires W alternately connected to upper surfaces and lower surfaces of the plurality of solar cells C.

A wire jig J may fix the wire W such that the wire W does not get floated or deviated from a designated position, when the solar cell C and the wire W are connected to each other. As illustrated in FIG. 1, while the wire W is arranged on a conveyor 41 of a wire transportation apparatus 40, the wire jig J may be mounted on the conveyer 41 to press the wire W. Also, the wire jig J may be supported and transported by a delivering apparatus 50 to be described below.

According to an embodiment, as illustrated in FIG. 1, the tabbing apparatus 1 may include the alignment apparatus 10, a solar cell transportation apparatus 20, a solar cell splitting apparatus 30, the wire transportation apparatus 40, the delivering apparatus 50, a bonding apparatus 60, the wire jig transportation apparatus 70, a controller 80, and a cell-jig transportation apparatus 90.

The alignment apparatus 10 may be an alignment apparatus for aligning a position of the solar cell C transported by the solar cell transportation apparatus 20. The alignment apparatus 10 may correct the position of the solar cell C by considering a position thereof with respect to the wire W mounted on the wire transportation apparatus 40, before the delivering apparatus 50 transports the wire jig J and the solar cell C. Operations of the alignment apparatus 10 will be described below.

The solar cell transportation apparatus 20 may receive the solar cell C from the outside, and transport the provided solar cell C. The solar cell transportation apparatus 20 including a conveyor may move the solar cell C to the solar cell splitting apparatus 30. Here, the solar cell C may be in a state in which the solar cell C is not split (scribed) into a predetermined size.

The solar cell splitting apparatus 30 may split the solar cell C transported by the solar cell transportation apparatus 20 into a required size. The solar cell splitting apparatus 30 may include a scriber 31, and the scriber 31 may split the solar cell C into a plurality of segments by using a laser method or a mechanical method.

The wire transportation apparatus 40 may receive the wire W from the outside, and move the provided wire W. The wire transportation apparatus 40 may include a conveyor 41, a roller 43, and an aligner 45.

The conveyor 41 may include a flat upper surface so that a plurality of wires W may move while being apart from each other. The roller 43 may be arranged at an end of the wire transportation apparatus 40 so that the wire W may be transported while being mounted on the upper surface of the conveyor 41. The roller 43 may be arranged at each of a side and another side of the wire transportation apparatus 40 such that the conveyor 41 may be arranged between the rollers 43 arranged at both of the side and the other side of the wire transportation apparatus 40, according to an embodiment. The aligner 45 may primarily align the wire W before the solar cell C and the wire W contact each other, that is, before the solar cell C is arranged on the wire W. The aligner 45 may include a plurality of grooves or protrusions, the number of which corresponds to the plurality of wires W, so that the wires W may move along predetermined paths.

The delivering apparatus 50 may move the solar cell C and the wire jig J toward the wire W. According to an embodiment, the delivering apparatus 50 may include a first frame 51, a second frame 53, and a position identification sensor 55. The first frame 51 and the second frame 53 may be arranged to cross each other, and the first frame 51 may be arranged to be movable between a pair of second frames 53. The first frame 51 may extend in a first direction, that is, an X-axis direction, and may move in a second direction in which the second frame 53 extends, that is, a Y-axis direction. Also, the cell jig transportation apparatus may be arranged at a side of the first frame 51 and may move along with the first frame 51. Also, the cell-jig transportation apparatus 90 may pick up an object by using an absorption method, a method using an electromagnetic force, or a mechanical method.

The position identification sensor 55 may be arranged at an end of the tabbing apparatus 1 and may identify a position of the solar cell C. The position identification sensor may independently operate from other elements of the tabbing apparatus 1, such as the cell-jig transportation apparatus 90, and may be provided to be movable along with the first frame 51. Before the cell-jig transportation apparatus 90 transports the solar cell C, the position identification sensor 55 may move to the alignment apparatus 10, and, after identifying the position of the solar cell C mounted on the alignment apparatus 10, may transmit the position of the solar cell C to the controller 80. Based on position information sensed by the position identification sensor 55, the controller 80 may correct the position of the solar cell C by controlling the alignment apparatus 10. According to an embodiment, the position identification sensor 55 may be a vision camera. Alternatively or additionally, the position identification sensor 55 may be or include a laser sensor, an ultrasonic sensor, or an electro-magnetic sensor.

FIG. 1 illustrates that the position identification sensor 55 is mounted on the delivering apparatus 50. However, the disclosure is not limited thereto. The position identification sensor 55 may be mounted on the cell-jig transportation apparatus 90, the alignment apparatus 10, the wire jig transportation apparatus 70, or the like. Also, the position identification sensor 55 may independently operate from the cell jig transportation apparatus 90.

The bonding apparatus 60 may bond the solar cell C with the wire W contacting the solar cell C. The bonding apparatus 60 may include a soldering apparatus configured to inject solder onto a connection portion or interface of the solar cell C and the wire W, and heat the injected solder to bond the solar cell C and the wire W to each other. Alternatively or additionally, the bonding apparatus 60 may include an apparatus configured to inject an electro-conductive adhesive onto the connection portion or interface of the solar cell C and the wire W to bond the solar cell C and the wire W to each other.

The wire jig transportation apparatus 70 may receive the wire jig J from the outside, and transport the wire jig J. The wire jig transportation apparatus 70 including a conveyor may transport the wire jig J toward the delivering apparatus 50 so that the delivering apparatus 50 may pick up the wire jig J.

According to an embodiment, as illustrated in FIG. 4, the wire jig transportation apparatus 70 may include a transportation rail 71, a support frame 72, and a stopper 73.

The transportation rail 71 supported by a ground surface or another apparatus through the support frame 72 may move a plurality of wire jigs J in a direction, that is, an X-axis direction.

The stopper 73 may be arranged at a front end of the transportation rail 71, and may hold the wire jig J. As illustrated in FIG. 4, the stopper 73 may be arranged at an end of the transportation rail 71 in a direction in which the wire jig J is transported. The stopper 73 may protrude from an upper surface of the transportation rail 71 so as to hold the wire jig J not to be deviated. Also, the stopper 73 may have ready a wire jig J from among a plurality of wire jigs J, the wire jig J being to be supported by the cell-jig transportation apparatus 90. The cell jig transportation apparatus 90 may simultaneously support the wire jig J held ready by the stopper 73 and the solar cell C mounted on a stage 200.

According to an embodiment, the wire jig transportation apparatus 70 may transport the plurality of wire jigs J at a time interval. As illustrated in FIG. 4, the wire jig transportation apparatus 70 may serially transport the plurality of wire jigs J through the transportation rail 71 at a regular interval. Also, when the wire jig J supported by the cell-jig transportation apparatus 90 is held by the stopper 73, the wire jig transportation apparatus 70 may transport a wire jig J of a next order at a time interval for maintaining a predetermined gap L between the wire jig J held by the stopper 73 and the wire jig J of the next order. That is, the wire jig transportation apparatus 70 may sequentially transport the plurality of wire jigs J toward the stopper 73, wherein the wire jig transportation apparatus 70 may transport a wire jig J of a next order after a predetermined time period, so that a wire jig J maintains a predetermined gap L with a wire jig contacting the stopper 73 and getting near, that is, the wire jig J of the next order. Accordingly, when the cell-jig transportation apparatus 90 supports the wire jig J, interference by other adjacent wire jigs J may be prevented.

According to an embodiment, the wire jig transportation apparatus 70 may further include a position identification sensor 74. As illustrated in FIG. 4, the position identification sensor 74 may be arranged at a side of the transportation rail 71 or the stopper 73, and may identify the position of the solar cell C mounted on the stage 200.

The controller 80 may control other elements of the tabbing apparatus 1. The controller 80 may communicate with, in a wired or wireless manner, and control the alignment apparatus 10, the solar cell transportation apparatus 20, the solar cell splitting apparatus 30, the wire transportation apparatus 40, the delivering apparatus 50, the bonding apparatus 60, the wire jig transportation apparatus 70, and the cell-jig transportation apparatus 90. According to an embodiment, the controller 80 may control the alignment apparatus 10 and the delivering apparatus 50, and control operations of correcting the position of the solar cell C and delivering the solar cell C. Operations of the controller 80 will be described below.

The controller 80 may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware to perform the functions or operations described herein.

The alignment apparatus 10 is described with reference to FIGS. 1 to 4.

The alignment apparatus 10 may be arranged to be adjacent to the solar cell splitting apparatus 30, and the wire jig transportation apparatus 70. As illustrated in FIG. 1, the alignment apparatus 10 may be arranged between the solar cell splitting apparatus 30 and the wire jig transportation apparatus 70. Before the delivering apparatus 50 supports the solar cell C and the wire jig J, the alignment apparatus 10 may correct the position of the solar cell C, so that the wire W and the solar cell C may be bonded to each other at an appropriate position, which may be a corrected position of the solar cell C.

According to an embodiment, the alignment apparatus 10 may include a base 100, the stage 200, a first displacement device 300, a second displacement device 400, and a third displacement device 500.

The base 100 may be arranged at one end of the alignment apparatus 10, and may support the stage 200 above the first displacement device 300, the second displacement device 400, and the third displacement device 500. As illustrated in FIG. 2, the base 100 may have a flat plate shape, and may be arranged above the third displacement device 500. According to an embodiment, the base 100 may have a greater area than the solar cell C.

The stage 200 may directly support the solar cell C. The solar cell C transported by the solar cell transportation apparatus 20 may be mounted on the stage 200, and the stage 200 may fix the solar cell C not to move while the solar cell is supported or aligned. According to an embodiment, the stage 200 may be connected to a negative pressure source, and may support the solar cell C by absorbing the solar cell C. A plurality of absorption holes may be provided on an upper surface of the stage 200 on which the solar cell C is mounted, and may absorb and support the solar cell C so that the solar cell C may not move when the stage 200 moves or the cell-jig transportation apparatus 90 supports the solar cell C. Alternatively, the stage 200 may include a clamp, a gripper, or the like mechanically supporting the solar cell C.

The alignment apparatus 10 according to an embodiment may include a plurality of displacement devices for correcting a position of the solar cell C. The alignment apparatus 10 may include the first displacement device 300, the second displacement device 400, and the third displacement device 500 as the plurality of displacement devices.

The first displacement device 300 may be arranged at a lower end of the alignment apparatus 10, and may move the position of the solar cell C in one direction. The first displacement device 300 may move the solar cell C in a direction in which the wire transportation apparatus 40 transports the wire W, that is, an X-axis direction.

According to an embodiment, the first displacement device 300 may include a bottom plate 310, a first rail 320, a first slider 330, a top plate 340, and a first driving element 350.

The bottom plate 310 may be arranged at a lowermost end of the first displacement device 300, and may connect the alignment apparatus 10 to a floor or another apparatus. The shape and the size of the bottom plate 310 are not particularly limited, and it may suffice when the bottom plate 310 may flatly support the first displacement device 300 and the alignment apparatus 10.

The first rail 320 may include one or more first rails 320 arranged on the bottom plate 310 in one direction. Two first rails 320 may be arranged on the bottom plate 310 in parallel with an X-axis.

The first slider 330 may be connected to each of the first rails 320 to be slidable. As the first slider 330 moves, the top plate 340 may move in a lengthwise direction of the first rail 320, that is, the X-axis direction. Accordingly, the second displacement device 400, the third displacement device 500, the base 100, the stage 200, and the solar cell C mounted on the stage 200 may also move in the X-axis direction.

The first driving element 350 may be connected to the first slider 330 and/or the top plate 340, and may move the first slider 330 and/or the top plate 340 in the X-axis direction. Types of the first driving element 350 are not particularly limited and may include a step motor, a linear motor, a hydraulic cylinder, or the like.

The second displacement device 400 may be arranged on the first displacement device 300, and may move the position of the solar cell C in one direction. The second displacement device 400 may move the solar cell C in a movement direction of the cell-jig transportation apparatus 90, that is, a Y-axis direction.

According to an embodiment, the second displacement device 400 may include a body 410, a second slider 420, and a second driving element 430.

The body 410 may be arranged on the top plate 340, and may include an inner space in which the second driving element 430 to be described below is arranged. The body 410 may be fixed on the top plate 340, and may move in the same direction as the top plate 340 moves.

The second slider 420 may be mounted on the body 410 to be slidable. The second slider 420 connected to the second driving element 430 may move in a lengthwise direction of the second driving element 430, that is, the Y-axis direction. The second slider 420 may be connected to the third displacement device 500, and may move the third displacement device 500, the base 100, and the stage 200. Types of the second driving element 430 are not particularly limited and may include a step motor, a linear motor, a hydraulic cylinder, or the like.

The third displacement device 500 may be arranged on the second displacement device 400, and may move the position of the solar cell C in one direction. The third displacement device 500 may rotate the solar cell C with respect to a Z-axis.

According to an embodiment, the third displacement device 500 may include a spindle 510 and a third driving element 520.

The spindle 510 may be directly connected to the base 100, and may rotate with respect to the Z-axis according to an operation of the third driving element 520. Accordingly, the base 100 and the stage 200 may rotate, and an angle of the solar cell C mounted on the stage 200 with respect to the Z-axis may be corrected. Types of the third driving element 520 are not particularly limited, and may include a step motor, a linear motor, a hydraulic cylinder, or the like.

FIG. 2 illustrates that the first displacement device 300 is arranged at the lowermost end, and the second displacement device 400 and the third displacement device 500 are sequentially arranged thereon. However, the order of arrangement of the first to third displacement devices 300 to 500 is not particularly limited. The first displacement device 300 or the second displacement device 400 may be arranged at the uppermost end to be connected to the base 100.

According to an embodiment, the alignment apparatus 10 may correct a position of the solar cell C based on a command of the controller 80. While the solar cell C is being mounted on the stage 200, the tabbing apparatus 1 may perform a process of correcting the position of the solar cell C before supporting the solar cell C. As illustrated in FIG. 3, when the position of the solar cell C is deviated (indicated by a solid-line rectangle) from a desirable position (indicated by a dashed-line rectangle), and when in this state, the solar cell C is supported and mounted on the wire W, the solar cell C and the wire W may not be properly bonded to each other. Thus, the controller 80 may command the alignment apparatus to correct the position of the solar cell C.

The controller 80 may determine, based on position information about the wire transportation apparatus 40, a position on which the solar cell C is to be mounted, and may control the alignment apparatus 10 based on information about the determined position. That is, the controller 80 may use the position information about the wire transportation apparatus which is fixed or has a fixed position, in the tabbing apparatus 1, as a reference value for controlling the alignment apparatus 10.

As illustrated in FIG. 3, the controller 80 may obtain position information about a vertex P₀ (X₀, Y₀) of a corner (or edge) portion of the solar cell C to be mounted on the wire W, based on a position of a corner (or edge) portion of the wire transportation apparatus 40, that is, a position of a vertex P_{S1} (X_{S1}, Y_{S1}) of the corner portion. In other words, based on the position of the wire transportation apparatus 40, which is fixed, the position on which the solar cell C is to be mounted may be determined. Here, distances between P_{S1} and P₀ may be D_{X1}, D_{Y1}, and these may be pre-stored values. Also, the controller 80 may pre-store position information of P_{S1} and P₀.

Next, the controller 80 may receive position information P_{C} (X_{C}, Y_{C}) about the solar cell C from the position identification sensor 55. Here, the position identification sensor may be an independent position identification sensor 55, a position identification sensor provided in the cell jig transportation apparatus 90, or a position identification sensor provided in the wire jig transportation apparatus 70.

Also, the controller 80 may calculate, based on P₀, a corrected position of the solar cell C, that is, a position that the solar cell C needs to be corrected to when the solar cell C is not correctly positioned. According to an embodiment, the cell-jig transportation apparatus 90 may mount the solar cell C and the wire jig J on the wire W by moving in the Y-axis direction while supporting the solar cell C and the wire jig J. Thus, a correct position of the solar cell C and a position of the solar cell C mounted on the wire W may be different from each other only in the Y-axis direction. Thus, the controller 80 may obtain the correct position of the solar cell C, that is, a position P₁ (X₁, Y₁) of the corner portion, based on the pre-set value P₀. Also, the controller 80 may calculate P₁ and calculate a position difference and an angle difference between P₁ and P_{C} indicating a current position of the solar cell C. That is, based on the current position P_{C} of the solar cell C and the position P₀ of the solar cell C, the controller 80 may calculate position differences in an X direction and a Y direction and an angle difference θ on an X-Y plane. Based on the calculated position differences, the controller 80 may command the alignment apparatus 10 to perform position alignment.

When the alignment apparatus 10 is commanded by the controller 80, the alignment apparatus 10 may operate the first displacement device 300 and the second displacement device 400 to adjust the position of the mounted solar cell C in the X direction and the Y direction. Also, the alignment apparatus 10 may operate the third displacement device 500 to adjust the position of the mounted solar cell C in a 0 direction. When the alignment operation is completed, the alignment apparatus 10 may notify the controller 80 of the completion of the alignment, and the controller 80 may control the delivering apparatus 50 to deliver the solar cell C and the wire jig J.

According to an embodiment, after the alignment apparatus 10 corrects the position of the solar cell C, the position identification sensor may identify once again the corrected position of the solar cell C. When the alignment apparatus 10 notifies the controller of the completion of the alignment, the controller 80 may move the position identification sensor 55 to the alignment apparatus 10. The position identification sensor 55 may identify the corrected position of the solar cell C, and transmit the identified position to the controller 80. When the identified position of the solar cell C is within a first predetermined range, the controller 80 may control the delivering apparatus 50 to deliver the solar cell c and the wire jig J. Alternatively, when the identified position of the solar cell C is within a second predetermined range, the controller 80 may control the alignment apparatus 10 to once again correct the position of the solar cell C before controlling the delivering apparatus 50 to deliver the solar cell c and the wire jig J.

According to another embodiment, the controller 80 may determine a position on which the solar cell C is to be mounted, based on position information about the wire jig transportation apparatus 70, and may control the alignment apparatus 10 based on information about the determined position. That is, the controller 80 may use the position information about the wire jig transportation apparatus 70, which is fixed or has a fixed position, in the tabbing apparatus 1, as a reference value for controlling the alignment apparatus 10.

According to an embodiment, as illustrated in FIG. 3, the controller 80 may obtain a corrected position of the solar cell C, that is, position information about the vertex P₁ (X₁, Y₁) of the corner portion, based on a position of a corner (or edge) portion of the wire jig transportation apparatus 70, that is, a position of a vertex P_{S2} (X_{S2}, Y_{S2}) of the corner portion. In other words, based on the position of the wire jig transportation apparatus 70, which is not changed like the position of the wire transportation apparatus 40, the corrected position of the solar cell C, that is, position that the solar cell C needs to be corrected to when the solar cell C is not correctly positioned may be determined. Here, distances between P_{S2} and P1 may be D_{X2}, D_{Y2}, and these may be pre-stored values. Also, the controller 80 may pre-store position information about P_{S2} and P₁.

Next, the controller 80 may receive position information P_{C} (X_{C}, Y_{C}) about the solar cell C from the position identification sensor 55. Here, the position identification sensor 55 may be an independent position identification sensor 55, a position identification sensor provided in the cell jig transportation apparatus 90, or a position identification sensor provided in the wire jig transportation apparatus 70.

Also, the controller 80 may calculate, based on P₁ and P_{C}, amounts of displacement in the X direction, the Y direction, and the θ direction that are required for correction. Based on a calculated position difference, the controller 80 may command the alignment apparatus 10 to perform position alignment.

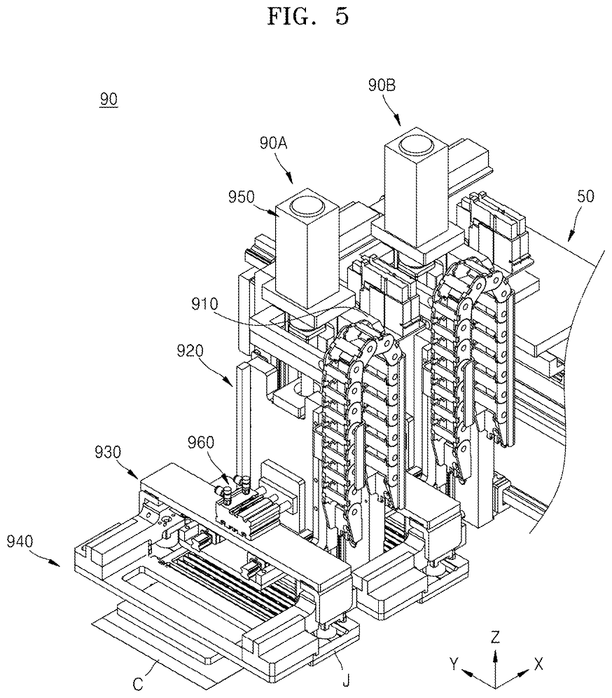

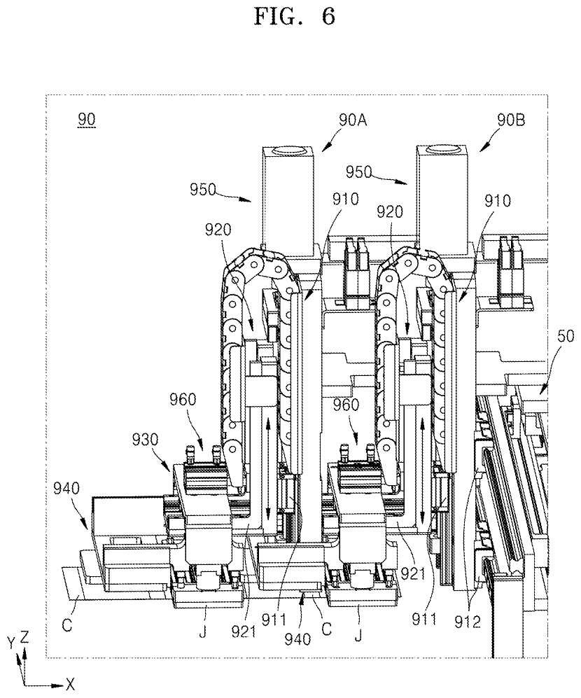

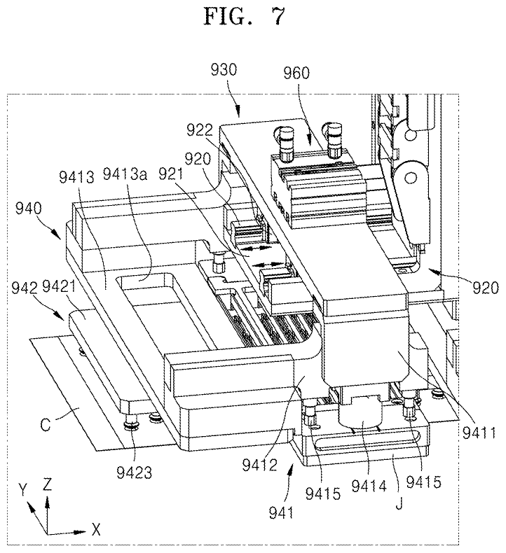

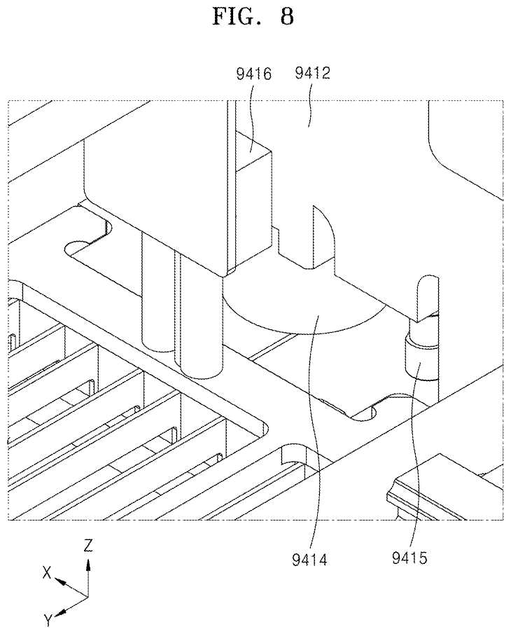

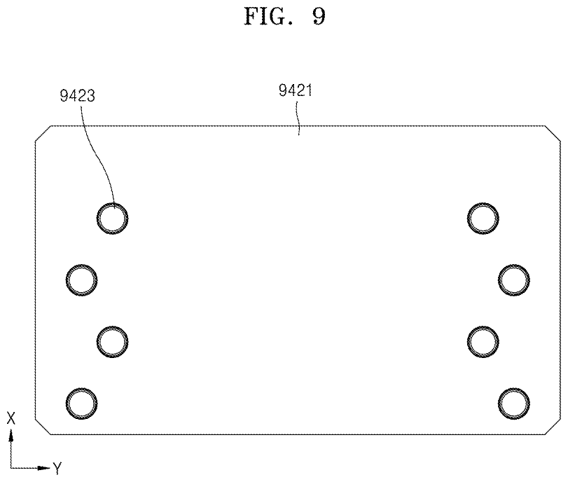

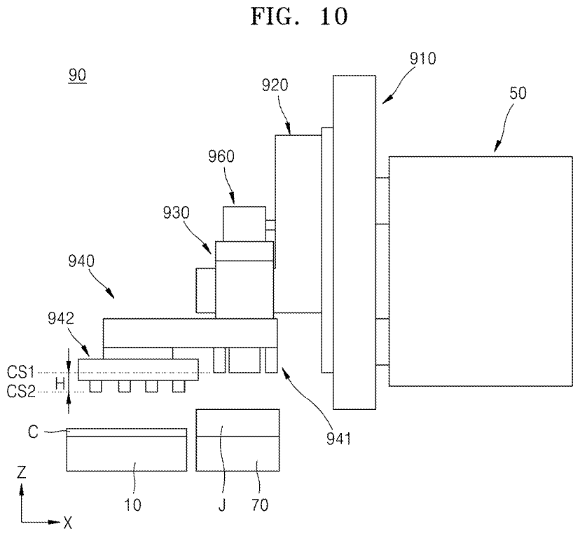

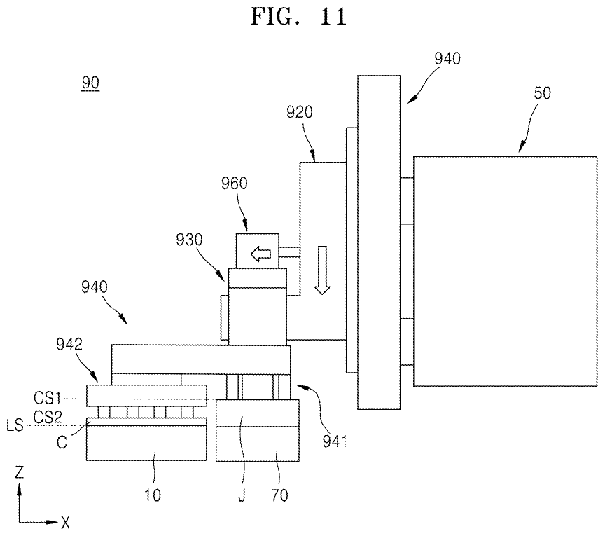

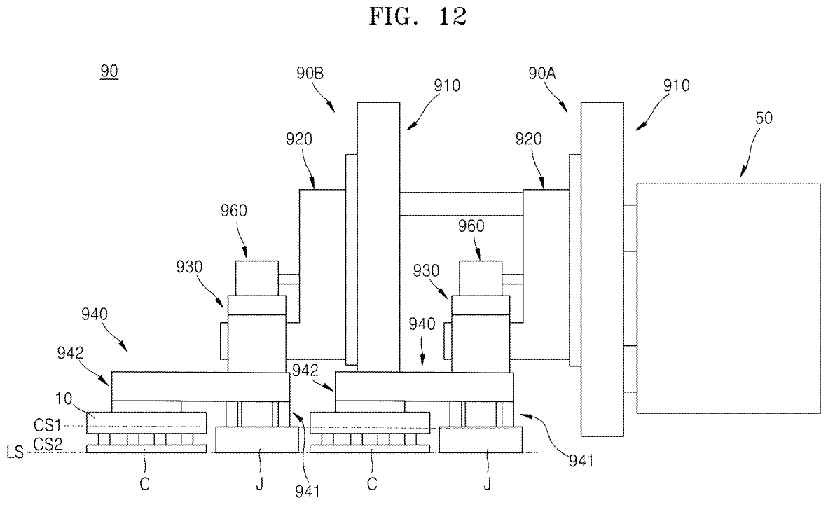

FIG. 5 is a perspective view of the cell-jig transportation apparatus 90 according to an embodiment. FIG. 6 is a side view of the cell-jig transportation apparatus 90 according to an embodiment. FIG. 7 is an enlarged view of the cell-jig transportation apparatus 90 according to an embodiment. FIG. 8 is an enlarged view of a first support structure according to an embodiment. FIG. 9 is a view of a bottom surface of a second support structure according to an embodiment. FIGS. 10 and 11 illustrate an operation of the cell-jig transportation apparatus 90, according to an embodiment. FIG. 12 illustrates an operation of the cell jig transportation apparatus 90, according to another embodiment.

The cell jig transportation apparatus 90 according to an embodiment is described with reference to FIGS. 1, 2, and 5 to 9.

The cell jig transportation apparatus 90 may be connected to the delivering apparatus 50 to move in a lengthwise direction of the delivering apparatus 50, that is, a first direction, and may transport the solar cell C and the wire jig J. The cell jig transportation apparatus 90 may support the solar cell C mounted on a stage of the alignment apparatus 10 33 and the wire jig J mounted on the wire jig transportation apparatus 70, and in this state, may be moved onto the wire transportation apparatus 40 by the delivering apparatus 50. Also, the cell-jig transportation apparatus 90 may mount the solar cell C and the wire jig J on the wire W and may perform processes of fixing the wire W and connecting the wire W with the solar cell C.

According to an embodiment, the cell-jig transportation apparatus 90 may include one or more cell-jig transportation apparatuses. One cell-jig transportation apparatus 90 may be connected to the delivering apparatus 50. Alternatively, as illustrated in FIG. 5, the cell-jig transportation apparatus 90 may be provided in plural. For convenience of explanation, a single cell-jig transportation apparatus 90 connected to the delivering apparatus 50 is described first.

According to an embodiment, the cell-jig transportation apparatus 90 may include a main body 910, a first movement structure 920, a second movement structure 930, a support structure 940, a driving structure 950, and a stopping structure 960.

The main body 910 may support other components of the cell-jig transportation apparatus 90, and may be directly connected to the delivering apparatus 50. The main body 910 may have a plate shape, and may be connected to the delivering apparatus 50 to be slidable.

According to an embodiment, the main body 910 may include a first slider 911 and a second slider 912.

The first slider 911 may be arranged at one end of the main body 910, and may be connected to the first movement structure 920 to be described below. The first slider 911 may be movable in a height direction along a rail provided in the main body 910 and/or the first movement structure 920, that is, a third direction. Thus, while the main body 910 is being fixed, the first slider 911 may move in the third direction so that the first movement structure 920 may move. Also, the cell jig transportation apparatus 90 may adjust, through the first slider 911, a position of the support structure 940 to be described below in the height direction, and thus, may support the solar cell C and the wire jig J.

The second slider 912 may be arranged at another end of the main body 910, and may be connected to the delivering apparatus 50. As illustrated in FIG. 6, one or more second sliders 912 may be arranged on a surface of the main body 910, the surface facing the delivering apparatus 50, and may be connected to the delivering apparatus 50 to be slidable in a width direction of the main body 910, that is, the first direction. Thus, the main body 910 may directly move in the first direction, and the cell jig transportation apparatus 90 may adjust, through the second slider 912, the position of the support structure 940 described below in the height direction, and thus, may support the solar cell C and the wire jig J.

The first movement structure 920 may be connected to the main body 910, and may move in the height direction. One end of the first movement structure 920 may be connected to the first slider 911 of the main body 910, and another end of the first movement structure 920 may be connected to the second movement structure 930 described below. Thus, when the first movement structure 920 ascends along with an operation of the first slider 911, the second movement structure 930 connected to the first movement structure 920 may also ascend, and thus, the position of the support structure 940 may be adjusted.

According to an embodiment, the first movement structure 920 may have a partially bent shape. As illustrated in FIGS. 5 and 6, a portion of the first movement structure 920, the portion facing the delivering apparatus 50, may have a plate shape extending straight in the height direction. Also, with a lower end of the first movement structure 920 protruding toward an opposite side of the delivering apparatus 50, the first movement structure 920 may generally have an L shape. As illustrated in FIG. 6, the first movement structure 920 may include a protrusion area 921.

A rail may be provided at an upper end of the protrusion area 921, and through a third slider 922 mounted on the rail, the second movement structure 930 to be described below may be connected to the first movement structure 920 to be slidable. The third slider 922 may be movable in a lengthwise direction of the protrusion area 921, that is, the second direction. Thus, the second movement structure 930 connected to the third slider 922 may move in the second direction, and thus, the position of the support structure 940 may be adjusted.

The second movement structure 930 may be connected to the first movement structure 920, and may move along with the first movement structure 920. As illustrated in FIGS. 5 and 6, the second movement structure 930 may be arranged at a side of the first movement structure 920 above the protrusion area 921. A lower surface of the second movement structure 930 may be connected to the third slider 922 mounted on the rail of the protrusion area 921 and may integrally move along with the third slider 922.

According to an embodiment, the second movement structure 930 may have a flat plate shape. Also, the second movement structure 930 may have a greater width than the first movement structure 920, and may have a width equal to or greater or less than a width of the wire jig J. Also, in a plan view, the second movement structure 930 may be arranged on the wire J while the cell jig transportation apparatus 90 is supporting the wire jig J.

The support structure 940 may be connected to the second movement structure 930, and may directly support the solar cell C and the wire jig J. As illustrated in FIGS. 5 to 7, the support structure 940 may be arranged at a side of the second movement structure 930, and may move together with the second movement structure 930. Thus, when the cell jig transportation apparatus 90 moves in the first direction along with the delivering apparatus 50, the first movement structure 920 moves in the third direction, or the second movement structure 930 moves in the second direction, the support structure 940 may move accordingly and may correct a position to support the solar cell C and the wire jig J.

According to an embodiment, the support structure 940 may include a first support structure 941 and a second support structure 942.

The first support structure 941 may support the wire jig J, and may be connected to the second movement structure 930. As illustrated in FIG. 7, the first support structure 941 may be arranged below the second movement structure 930, and may be arranged on the wire W while supporting the wire jig J.

According to an embodiment, the first support structure 941 may include a connector, a first body 9413, a first support element 9414, and a second support element 9415.

The connector may connect the first support structure 941 with the second support structure 942. The connector may include a first connector 9411 and a second connector 9412.

The first connector 9411 may be connected to the second movement structure 930. As illustrated in FIG. 7, the first connector 9411 may be arranged at each of both ends of the second movement structure 930 in a lengthwise direction, and may extend downwardly. The first connector 9411 may connect the second movement structure 930 with the first support structure 941.

The second connector 9412 may be arranged to correspond to the first connector 9411, and may connect the first connector 9411 with the first body 9413. The second connector 9412 may be arranged at each of both ends of the second movement structure 930 in the lengthwise direction to correspond to the first connector 9411. Also, an end of the second connector 9412 may be connected to the first connector 9411, and another end of the second connector 9412 may extend in the second direction to be connected to the first body 9413.

The second connector 9412 may support the first support element 9414 and the second support element 9415 to be described below. As illustrated in FIG. 7, each of the first support element 9414 and the second support element 9415 may be arranged below one end of the second connector 9412, the one end being connected to the first connector 9411.

The first body 9413 may be arranged at a side of the second connector 9412, and may connect the first support structure 941 with the second support structure 942. Each of upper surfaces of both ends of the first body 9413 in the lengthwise direction may be connected to the second connector 9412, each of lower surfaces may be connected to an upper surface of the second support structure 942 to be described below. Thus, when the first support structure 941 connected to the second movement structure 930 moves, the second support structure 942 may integrally move.

The first support element 9414 may be connected to the second connector 9412, and may directly contact the wire jig J. As illustrated in FIG. 7, the first support element 9414 may be connected to each of a pair of second connectors 9412, and one end of the first support element 9414 may contact both ends of an upper surface of the wire jig J in a lengthwise direction. Thus, the first support element 9414 may support the wire jig J.

According to an embodiment, the first support element 9414 may include an electronic chuck. The first support element 9414 may include an electromagnet at an end thereof facing the wire jig J. Accordingly, when currents flow in the first support element 9414, a magnetic force may be generated to support the wire jig J.

FIG. 7 illustrates that a pair of first support elements 9414 are provided to correspond to the number of second connectors 9412. However, the first support element 9414 is not limited thereto. A plurality of first support elements 9414 may be arranged with respect to one second connector 9412.

The second support element 9415 may be connected to the second connector 9412, and may directly contact the wire jig J. As illustrated in FIG. 7, the second support element 9415 may be connected to each of the pair of second connectors 9412, and one end of the second support element 9415 may contact both ends of the upper surface of the wire jig J in the lengthwise direction. Thus, the second support element 9415 may support the wire jig J.

According to an embodiment, the second support element 9415 may support the wire jig J by using an absorption method. The second support element 9415 may be connected to a negative pressure source, and may support the wire jig J by absorbing the wire jig J. Also, the second connector 9412 may include a negative pressure path corresponding to the second support element 9415.

According to an embodiment, the second support element 9415 may be provided in plural, and the first support element 9414 may be arranged between the plurality of second support elements 9415. As illustrated in FIG. 7, two second support elements 9415 may be arranged with respect to one second connector 9412, and may respectively contact both ends of the upper surface of the wire jig J in a width direction. Also, the first support element 9414 may be arranged between two second support elements 9415. As described above, the first support structure 941 may use different support elements to stably support the wire jig J. Also, the first support element 9414 may support the wire jig J with a relatively intense force, and the plurality of second support elements 9415 adjacent to the first support element 9414 may support the wire jig J, and thus, during a pick-up, movement, or mounting process, the wire jig J may not be shaken or deviated from its position.

FIG. 7 illustrates that two second support elements 9415 are arranged with respect to one second connector 9412. However, the second support elements 9415 are not limited thereto. Three or more second support elements 9415 may be provided with respect to one second connector 9412.

According to an embodiment, the first support structure 941 may further include a wire jig sensing sensor 9416. As illustrated in FIG. 8, the wire jig sensing sensor 9416 may be arranged at a side of the second connector 9412. The wire jig sensing sensor 9416 may sense whether the first support structure 941 and the wire jig J contact each other, and may sense a contact pressure thereof, etc. during a process in which the first support structure 941 supports the wire jig J. Thus, the wire jig sensing sensor 9416 may determine whether the first support structure 941 appropriately supports the wire jig J.

The second support structure 942 may be arranged at a side of the first support structure 941 to integrally move with the first support structure 941. As illustrated in FIGS. 5 to 7, the second support structure 942 may be connected to a forwardly protruding end of the first support structure 941, that is, the first body 9413. The second support structure 942 may support the solar cell C.

According to an embodiment, the second support structure 942 may include a second body 9421 and a third support element 9423.

As illustrated in FIGS. 7 and 9, the second body 9421 may have a flat plate shape. The second body 9421 may be arranged below the first body 9413 to correspond to the solar cell C.

According to an embodiment, the second body 9421 may include a negative pressure path inside thereof. The negative pressure path may be arranged to correspond to the third support element 9423 to be described below.

The third support element 9423 may be arranged at a side of the second body 9421, and may directly contact and support the solar cell C. As illustrated in FIGS. 7 and 9, the third support element 9423 may be arranged in plural on a bottom surface of the second body 9421, and may have one end extending toward the solar cell C. The number of third support elements 9423 is not particularly limited, and the third support elements 9423 may be provided in plural to form a horizontal symmetry.

The same number of third support elements 9423 may be provided at each of both ends of the second body 9421 in a width direction. According to an embodiment, the plurality of third support elements 9423 may be arranged to be misaligned with each other. As illustrated in FIG. 9, the third support element 9423 in a second column, arranged at an outermost area of the second body 9421, and the third support element 9423 in the second column, arranged at an inner area of the outermost area of the second body 9421, may be misaligned with each other. In particular, the plurality of third support elements 9423 may be arranged in different columns from each other in a lengthwise direction and the width direction of the second body 9421. Thus, the plurality of third support elements 9423 may not just support a predetermined portion of the solar cell C, but may support a wide range of the solar cell C as possible, so as to stably support the solar cell C and prevent transformation, for example, bending, etc., of the solar cell C, in the process of supporting and moving the solar cell C.

According to an embodiment, the third support element 9423 may support the solar cell C by using an absorption method. The third support element 9423 may be connected to a negative pressure source, and may absorb and support the solar cell C.

The driving structure 950 may operate the cell jig transportation apparatus 90. The driving structure 950 may move the support structure 940 by moving the first movement structure 920 and the second movement structure 930.

As illustrated in FIGS. 5 to 7, the stopping structure 960 may be arranged on the second movement structure 930, and may have one end connected to the first movement structure 920. The stopping structure 960 may restrict movement of the second movement structure 930 in the second direction. While the cell jig transportation apparatus 90 is being positioned on the solar cell C and the wire jig J, the second movement structure 930 may move in the second direction. Here, one end of the stopping structure 960 may be connected to the first movement structure 920, so that the second movement structure 930 may not move in a range greater than or equal to a predetermined value. The stopping structure 960 may be an electronic cylinder, and may adjust a position of the second movement structure 930 by limiting a maximum movement distance.

A tabbing method and a method of aligning a position of the solar cell C, according to an embodiment, are described with reference to FIGS. 1 to 12.

First, the solar cell transportation apparatus 20 may receive the solar cell C from the outside, and transport the solar cell C. The solar cell transportation apparatus 20 may sequentially provide a plurality of solar cells C. FIG. 1 illustrates that the solar cell transportation apparatus 20 includes one conveyor or transportation line. However, the solar cell transportation apparatus 20 is not limited thereto. The solar cell transportation apparatus 20 may include a plurality of conveyors or transportation lines to simultaneously provide the plurality of solar cells C.

The solar cell C may be transported to the solar cell splitting apparatus 30. The solar cell splitting apparatus 30 may split the initially provided solar cell C into a size appropriate for a solar cell module. The solar cell splitting apparatus 30 may split the solar cell C into the appropriate size by using the scriber 31.

Also, the wire transportation apparatus 40 may supply the wire W. The wire transportation apparatus 40 may transport the wire W at the same time point as or a different time point from a time point at which the solar cell transportation apparatus 20 transports the solar cell C. By considering a speed by which the solar cell transportation apparatus 20 transports the solar cell C, the wire transportation apparatus 40 may transport the wire W according to a time taken for mounting the solar cell C and the wire jig J on the wire W.

Also, the wire jig transportation apparatus 70 may supply the wire jig J. The wire jig transportation apparatus 70 may transport the wire jig J at a time point at which the solar cell transportation apparatus 20 transports the solar cell C and/or at a time point the same or different from a time point at which the wire transportation apparatus 40 transports the wire W. By considering a speed by which the solar cell transportation apparatus 20 transports the solar cell C and a speed by which the wire transportation apparatus 40 transports the wire W, the wire jig transportation apparatus 70 may transport the wire jig J according to a time taken for mounting the solar cell C and the wire jig J on the wire W.

Also, the alignment apparatus 10 may receive the solar cell C from the solar cell splitting apparatus 30, and align a position of the solar cell C. When the cell jig transportation apparatus 90 of the delivering apparatus 50 moves onto the stage 200 and the wire jig transportation apparatus 70, the position identification sensor 55 provided in the cell-jig transportation apparatus 90 may identify the position of the solar cell C mounted on the stage 200. Alternatively, before the cell-jig transportation apparatus 90 moves, the position identification sensor 55 independently operating from the cell jig transportation apparatus 90 may move onto the stage 200 and the wire jig transportation apparatus 70, and may identify the position of the solar cell C mounted on the stage 200. Alternatively, the position identification sensor 74 provided at one end of the wire jig transportation apparatus 70 may identify the position of the solar cell C mounted on the stage 200.

Also, the controller 80 may command the alignment apparatus 10 to perform position alignment, based on a reference value and the identified position of the solar cell C. The controller 80 may use position information about the wire transportation apparatus 40 and/or the wire jig transportation apparatus 70 as the reference value. According to an embodiment, the controller 80 may calculate or pre-store information about a position on which the solar cell C is to be mounted, by using position information about one or more corner portions and/or edge portions of the wire transportation apparatus 40. Alternatively, the controller 80 may calculate or pre-store information about a position on which the solar cell C is to be mounted, by using position information about one or more corner portions and/or edge portions of the wire jig transportation apparatus 70. Also, the controller 80 may calculate, based on the calculated or pre-stored information, an amount of displacement required for correcting the position of the solar cell C, and may control the alignment apparatus 10 according to the calculated amount of displacement.

The alignment apparatus 10 may be commanded by the controller 80, and may move in the X-axis direction and/or the Y-axis direction and may also rotate with respect to the Z-axis to correct the position of the solar cell C mounted on the stage 200.

When the position is corrected, the cell-jig transportation apparatus 90 of the delivering apparatus 50 may support the solar cell C and the wire jig J, and then may move to the wire transportation apparatus 40 to mount the solar cell C and the wire jig J on the wire W. According to an embodiment, the cell-jig transportation apparatus 90 may simultaneously support the solar cell C and the wire jig J and may simultaneously mount the solar cell C and the wire jig J on the wire W.

Operations of the cell-jig transportation apparatus 90, according to an embodiment, are described with reference to FIGS. 1 to 12.

As described above, when the position correction of the solar cell C by the alignment apparatus 10 is completed, the controller 80 may control the cell-jig transportation apparatus 90. According to an embodiment, the controller 80 may control the cell-jig transportation apparatus 90 to support (pick up) the solar cell C on the alignment apparatus 10 and the wire jig J on the wire jig transportation apparatus 70. Also, the controller 80 may control the cell-jig transportation apparatus 90 to move the solar cell C and the wire jig J to the wire W on the wire transportation apparatus 40 while the cell-jig transportation apparatus 90 is supporting the solar cell C and the wire jig J and to mount the solar cell C and the wire jig J on the wire W.

According to an embodiment, the cell-jig transportation apparatus 90 may move to a predetermined position along with the delivering apparatus 50 in order to support the solar cell C and the wire jig J. The cell jig transportation apparatus 90 may move in the first direction along with the delivering apparatus 50, and the first movement structure 920 may move in the third direction, that is, the height direction, with respect to the main body structure 910. Also, the first movement structure 920 may move in the second direction with respect to the second movement structure 930. Here, the first direction, the second direction, and the third direction may cross one another, and may be vertically arranged with respect to one another.

According to an embodiment, as illustrated in FIG. 10, the cell-jig transportation apparatus 90 may reach a predetermined position in the first direction along with the delivering apparatus 50. Also, the cell jig transportation apparatus 90 may control the first movement structure 920 and the second movement structure 930 to correct the position thereof in the second direction and the third direction. Here, the cell jig transportation apparatus 90 may further include a sensing sensor to identify whether the solar cell C and the wire jig J have reached a predetermined position. The sensing sensor may include an ultrasonic sensor, a vision sensor, a laser sensor, etc.

As illustrated in FIG. 10, when the cell-jig transportation apparatus 90 reaches a predetermined position in the first direction, the cell-jig transportation apparatus 90 may control the first movement structure 920 in order to correct a position of the support structure 940 in the third direction, that is, the height direction. The first movement structure 920 may adjust the position of the support structure 940 in the third direction by ascending with respect to the main body 910. Here, the first movement structure 920 may ascend to a height at which the support structure 940 may not directly contact the solar cell C and the wire jig J. Also, the cell jig transportation apparatus 90 may control the second movement structure 930 in order to correct the position of the support structure 940 in the second direction. The second movement structure 930 may control the position of the support structure 940 by moving in a horizontal direction in the drawing.

Also, the cell jig transportation apparatus 90 may identify the positions of the solar cell C, the wire jig J, and the support structure 940 by using the sensing sensor. When the positions are identified, the cell jig transportation apparatus 90 may have the first movement structure 920 descend so that the support 940 may simultaneously contact the solar cell C and the wire jig J to support the solar cell C and the wire jig J.

According to an embodiment, heights of surfaces at which the first support structure 941 and the second support structure 942 contact the wire jig J and the solar cell C respectively may be different from each other. For example, as illustrated in FIGS. 10 and 11, a first contact surface CS1 at which the first support structure 941 contacts the wire jig J may be higher by H than a second contact surface CS2 at which the second support structure 942 contacts the solar cell C. Accordingly, the first contact surface CS1 and the second contact surface CS2 may have different heights from each other.

According to an embodiment, the wire jig J and the solar cell C may be arranged on the same plane while being supported by the cell jig transportation apparatus 90. For example, as illustrated in FIG. 11, when the first support structure 941 and the second support structure 942 pick up the wire jig J and the solar cell C respectively, bottom surfaces of the wire jig J and the solar cell C may be arranged on the same plane LS. Accordingly, the cell-jig transportation apparatus 90 may move onto the wire W while supporting the wire jig J and the solar cell C, and then, may have the first movement structure 920 descend to simultaneously mount the wire jig J and the solar cell C on the wire W.

As described above, according to the cell jig transportation apparatus 90 according to an embodiment, the first support structure 941 and the second support structure 942 respectively supporting the wire jig J and the solar cell C may integrally move, and thus, the wire jig J and the solar cell C may be supported by a single operation. Also, the first support element 9414 and the second support element 9415 included in the first support structure 941 and the third support element 9423 included in the second support structure 942 may have ends at different heights from each other to form a step difference, and thus, may support the wire jig J and the solar cell C arranged at different heights from each other by performing a single operation.

Also, while the first support structure 941 and the second support structure 942 is supporting the wire jig J and the solar cell C, the bottom surfaces of the wire jig J and the solar cell C may be arranged on the same plane LS, and thus, the cell-jig transportation apparatus 90 may mount the wire jig J and the solar cell C on the wire W by performing a single operation.

Also, when the solar cell C and the wire jig J are mounted on the wire W, the wire transportation apparatus 40 may operate to move the solar cell C, the wire W, and the wire jig J. Also, the bonding apparatus 60 may electrically connect the solar cell C with the wire W, to finally manufacture a solar cell module.

FIG. 12 illustrates an operation of the cell-jig transportation apparatus 90, according to another embodiment.

The cell jig transportation apparatus 90 according to an embodiment may be provided in plural. For example, as illustrated in FIGS. 5, 6, and 12, the tabbing apparatus 1 may include the plurality of cell-jig transportation apparatuses 90. Also, the plurality of cell-jig transportation apparatuses 90 may integrally move through the delivering apparatus 50.

According to an embodiment, each of the plurality of cell-jig transportation apparatuses 90 may simultaneously support the solar cell C and the wire jig J, and then, may simultaneously mount the solar cell C and the wire jig J on the wire W. Accordingly, a process of arranging the solar cell C and the wire jig J may be performed at a much increased speed.

According to an embodiment, one of the plurality of cell-jig transportation apparatuses 90 may be directly connected to the delivering apparatus 50, and the others may be connected to the cell jig transportation apparatus 90 connected to the delivering apparatus 50. For example, as illustrated in FIGS. 5, 6, and 12, the plurality of cell jig transportation apparatuses 90 may include a first cell-jig transportation apparatus 90A and a second cell jig transportation apparatus 90B. Also, the first cell jig transportation apparatus 90A may be connected to the delivering apparatus 50, and may move in the second direction. Also, the second cell-jig transportation apparatus 90B may be connected to the first cell-jig transportation apparatus 90A, and may integrally move with the first cell jig transportation apparatus 90A.

According to an embodiment, the plurality of cell-jig transportation apparatuses 90 may be consecutively arranged in a direction perpendicular to a lengthwise direction of the delivering apparatus 50, that is, in the second direction. According to an embodiment, as illustrated in FIG. 12, the first cell-jig transportation apparatus 90A may be directly connected to the delivering apparatus 50, and the second cell-jig transportation apparatus 90B may be arranged in front of the first cell-jig transportation apparatus 90A in the second direction.

According to an embodiment, the main body 910 of any one of the cell jig transportation apparatuses 90 may be connected to the first movement structure 920 of an adjacent cell jig transportation apparatus 90. As illustrated in FIGS. 5, 6, and 12, the main body 910 of the second cell jig transportation apparatus 90B may be connected to the first movement structure 920 of the first cell-jig transportation apparatus 90A. Thus, when the first cell-jig transportation apparatus 90A moves in the first direction, the second direction, and the third direction, the second cell-jig transportation apparatus 90B may move likewise.

According to an embodiment, at least some components of the plurality of cell-jig transportation apparatuses 90 may independently operate from each other. For example, the second cell-jig transportation apparatus 90B may be connected to the first cell-jig transportation apparatus 90A and may integrally move with the first cell-jig transportation apparatus 90A, and at the same time, may individually control the first movement structure 920 and the second movement structure 930.

Therefore, the plurality of cell jig transportation apparatuses 90 may be integrally controlled to rapidly correct a position, and at the same time, the first movement structure 910 and the second movement structure 930 may be individually controlled to separately precisely correct the position with respect to the solar cell C and the wire jig J.

Although two cell jig transportation apparatuses 90 are illustrated in the drawing, the number of cell-jig transportation apparatuses 90 is not limited thereto. For example, three or more cell-jig transportation apparatuses 90 may be serially consecutively arranged.

According to a wire jig and a tabbing apparatus including the wire jig, according to an embodiment, floating and deviation of a wire may be prevented when a solar cell and the wire are bonded to each other, and thus, the solar cell and the wire may be satisfactorily bonded to each other.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A tabbing apparatus for forming a solar cell module by connecting a solar cell with a wire, the tabbing apparatus comprising:
a solar cell transportation apparatus configured to transport the solar cell;
a wire transportation apparatus configured to transport the wire;
a wire jig transportation apparatus configured to transport a wire jig that is configured to support the wire;
an alignment apparatus configured to mount thereon the solar cell transported by the solar cell transportation apparatus, and correct a position of the solar cell; and
a delivering apparatus configured to support the solar cell mounted on the alignment apparatus and having the corrected position and the wire jig transported by the wire jig transportation apparatus, and mount the solar cell and the wire jig on the wire on the wire transportation apparatus.

2. The tabbing apparatus of claim 1, wherein the alignment apparatus comprises a plurality of displacement devices including a first displacement device movable in a direction of an X-axis, a second displacement device movable in a direction of a Y-axis, and a third displacement device rotatable with respect to a Z-axis.

3. The tabbing apparatus of claim 1, further comprising:
a controller; and
a position identification sensor configured to identify the position of the solar cell mounted on the alignment apparatus,
wherein the controller is configured to correct the position of the solar cell, by controlling the alignment apparatus based on the position of the solar cell identified by the position identification sensor and a pre-stored reference value, and
wherein the controller is configured to control the alignment apparatus based on one or more of position information about the wire transportation apparatus and position information about the wire jig transportation apparatus as the reference value.

4. The tabbing apparatus of claim 1, wherein, after the delivering apparatus simultaneously supports the solar cell, the position of which is corrected by the alignment apparatus, and the wire jig, the delivering apparatus is configured to move to the wire transportation apparatus and simultaneously mount the solar cell and the wire jig on the wire.

5. The tabbing apparatus of claim 1, wherein the wire jig transportation apparatus comprises a stopper at an end thereof adjacent to the alignment apparatus, the stopper contacting the wire jig, and
wherein the delivering apparatus is configured to simultaneously support the solar cell mounted on the alignment apparatus and the wire jig contacting the stopper.

6. The tabbing apparatus of claim 1, wherein the delivering apparatus further comprises a cell-jig transportation apparatus, and
wherein the cell jig transportation apparatus comprises:
a main body;
a first movement structure connected to the main body to be movable in a first direction;
a second movement structure connected to the main body to be movable in a second direction which is different from the first direction; and
a first support structure and a second support structure each integrally moving with the second movement structure and respectively supporting the wire jig and the solar cell at a same time,
wherein the first support structure comprises a first contact surface facing the wire jig,
wherein the second support structure comprises a second contact surface facing the solar cell, and
wherein the first contact surface and the second contact surface have different heights from each other.

7. The tabbing apparatus of claim 6, wherein the first contact surface is arranged to be higher than the second contact surface, and
wherein a bottom surface of the wire jig and a bottom surface of the solar cell are arranged on a same plane.

8. The tabbing apparatus of claim 6, wherein, after the cell-jig transportation apparatus simultaneously supports the solar cell mounted on the alignment apparatus and the wire jig transported by the wire jig transportation apparatus, the cell jig transportation apparatus is configured to move along with the delivering apparatus, and mount the solar cell and the wire jig on the wire mounted on the wire transportation apparatus.

9. The tabbing apparatus of claim 6, wherein the cell-jig transportation apparatus is provided in plural to be integrally movable through the delivering apparatus, and,
wherein after each of the plurality of cell jig transportation apparatuses simultaneously supports the solar cell and the wire jig, each of the plurality of cell-jig transportation apparatuses is configured to simultaneously mount the solar cell and the wire jig on the wire.

10. The tabbing apparatus of claim 9, wherein the plurality of cell-jig transportation apparatuses comprise two cell-jig transportation apparatuses, and
wherein the main body of any one of the cell-jig transportation apparatuses is arranged on the second support structure of the other cell-jig transportation apparatus.

11. A tabbing method of forming a solar cell module by connecting a solar cell with a wire, the tabbing method comprising:
transporting the solar cell, the wire, and a wire jig supporting the wire, respectively via a solar cell transportation apparatus, a wire transportation apparatus, and a wire jig transportation apparatus;
correcting a position of the solar cell, using an alignment apparatus, while the alignment apparatus is supporting the solar cell transported by the solar cell transportation apparatus; and
after supporting the solar cell and the wire jig using a delivering apparatus, moving to the wire transportation apparatus and mounting the solar cell and the wire jig on the wire using the delivering apparatus.

12. The tabbing method of claim 11, comprising:
identifying the position of the solar cell mounted on the alignment apparatus using a position identification sensor;
correcting the position of the solar cell in at least three different directions by controlling the alignment apparatus based on the position of the solar cell using a controller; and
supporting the solar cell having the corrected position and the wire jig using the delivering apparatus.

13. The tabbing method of claim 12, wherein, after supporting the solar cell and the wire jig, moving the solar cell and the wire jig to the wire transportation apparatus and simultaneously mounting the solar cell and the wire jig on the wire using the delivering apparatus.

14. The tabbing method of claim 12, wherein correcting the position of the solar cell based on the position of the solar cell and a pre-stored reference value using the controller, and
wherein the reference value is one or more of position information about the wire transportation apparatus and position information about the wire jig transportation apparatus.

15. The tabbing method of claim 11, comprising:
sequentially transporting the wire jig in plural toward a stopper disposed at an end of the transportation apparatus adjacent to the alignment apparatus and contacting the wire jig; and
transporting a next wire jig after a predetermined time period so that the wire jig maintains a predetermined gap with a wire jig getting near after contacting the stopper.

16. The tabbing method of claim 11, wherein the delivering apparatus further comprises a cell-jig transportation apparatus, and
wherein the cell jig transportation apparatus comprises:
a main body;
a first movement structure connected to the main body to be capable of relative movement in a first direction;
a second movement structure connected to the main body to be capable of relative movement in a second direction which is different from the first direction; and
a first support structure and a second support structure each integrally moving along with the second movement structure and respectively simultaneously supporting the wire jig and the solar cell,
wherein the method comprises:
controlling a first contact surface of the first support structure to face the wire jig; and
controlling a second surface of the second support structure to face the solar cell, and
wherein the first contact surface and the second contact surface have different heights from each other.

17. The tabbing method of claim 16, comprising:
arranging the first contact surface to be higher than the second contact surface; and
arranging a bottom surface of the wire jig and a bottom surface of the solar cell on a same plane.

18. The tabbing method of claim 16, comprising:
after simultaneously supporting the solar cell mounted on the alignment apparatus and the wire jig transported by the wire jig transportation apparatus using the cell-jig transportation apparatus, moving the cell-jig transportation apparatus along with the delivering apparatus; and
mounting the solar cell and the wire jig on the wire mounted on the wire transportation apparatus.

19. The tabbing method of claim 16, comprising:
providing the cell jig transportation apparatus in plural to be integrally movable through the delivering apparatus; and,
after simultaneously supporting the solar cell and the wire jig, simultaneously mounting the solar cell and the wire jig on the wire using each of the plurality of cell-jig transportation apparatus.

20. The tabbing method of claim 19, comprising:
arranging the main body of one of the plurality of cell jig transportation apparatuses on the second support structure of another of the plurality of cell jig transportation apparatuses.
